(19) United States
(12) Patent Application Publication
(10) Pub. No.: US 2026/0211039 A1
(43) Pub. Date: Jul. 23, 2026

(54) DEGRADATION DIAGNOSIS APPARATUS, DEGRADATION DIAGNOSIS SYSTEM, AND DEGRADATION DIAGNOSIS METHOD

(71) Applicant: MITSUBISHI ELECTRIC CORPORATION, Tokyo (JP)

(72) Inventor: Yasuhiko WADA, Tokyo (JP)

(21) Appl. No.: 19/157,756

(22) PCT Filed: May 30, 2023
(86) PCT No.: PCT/JP2023/020114

§ 371 Date: Aug. 19, 2025

(51) Int. Cl. G01R 31/34

(52) U.S. Cl. CPC G01R 31/343

(57) ABSTRACT

A degradation diagnosis apparatus configured to diagnose progress of degradation of equipment in which a motor is installed, the degradation diagnosis apparatus comprising: a dynamic eccentricity estimating unit configured to estimate a degree of dynamic eccentricity of a rotation shaft constituting the equipment based on a current flowing through the motor, and a degradation diagnosis unit configured to diagnose a degree of shaft degradation related to the rotation shaft, based on the result of estimation.

### CROSS-REFERENCE TO RELATED APPLICATION

This application is a U.S. national stage application of PCT/JP2023/020114 filed on May 30, 2023, the contents of which are incorporated herein by reference.

### TECHNICAL FIELD

The present technology relates to a degradation diagnosis apparatus, a degradation diagnosis system, and a degradation diagnosis method for diagnosing the degradation of equipment. In particular, the present technology is directed to the diagnosis of degradation related to the rotation shaft included in the equipment.

### BACKGROUND

Equipment, such as a compressor which constitutes a refrigeration cycle apparatus, in which a motor is included that has a rotating shaft (hereafter referred to as a shaft) that transmits power from the motor, as well as bearings that support the shaft. For instance, when operating a compressor, the cause of failure of the motor is often due to degradation or damage of the bearings. When equipment is operated in a state where the bearing has worn and degraded, the motor stops, resulting in significant downtime (stopped time) in the operation of the compressor, thus reducing the operating rate of the compressor.

Therefore, it is desirable to predict the onset of failure from conditions of the motor bearings or other elements. Accordingly, it is preferable to take appropriate measures, such as repairing the motor bearings, before the degradation progresses to a point where the motor bearings degrade by abrasion and cause a failure. By doing this, it is possible to reduce or shorten the downtime of the compressor, increase the operating rate, and improve reliability. Therefore, a degradation diagnosis apparatus that diagnoses the condition of a rotating system by creating a distribution chart of Lissajous figures by layering two types of current data obtained from a current measurement section over multiple cycles has been proposed (for reference, see Patent Literature 1) based on the result of evaluation of the distribution chart.

### PATENT LITERATURE

[Patent Literature 1] WO2018/158910A

The degradation diagnosis apparatus in Patent Literature 1 estimates degradation using the Lissajous figure as an indicator from multiple phase currents. However, the degradation diagnosis apparatus in Patent Literature 1 does not anticipate events relating to the details of eccentricities occurring in the rotating shaft due to damage to components like bearings that compose the equipment. Therefore, in the degradation diagnosis apparatus of Patent Literature 1, it has been difficult to make a more precise diagnosis regarding the degradation related to the rotating shaft from the Lissajous figure.

### SUMMARY

Therefore, an object of the present disclosure is to provide a degradation diagnosis apparatus, a degradation diagnosis system, and a degradation diagnosis method that can diagnose degradation related to the rotating shaft more accurately in order to solve the aforementioned issues.

A degradation diagnosis apparatus according to an embodiment of the present disclosure is configured to diagnose progress of degradation of equipment in which a motor is installed, the degradation diagnosis apparatus including: a dynamic eccentricity estimating unit configured to estimate a degree of dynamic eccentricity of a rotation shaft constituting the equipment based on a current flowing through the motor, and a degradation diagnosis unit configured to diagnose a degree of shaft degradation related to the rotation shaft, based on a result of estimation.

A degradation diagnosis system according to an embodiment of the present disclosure includes a storage device configured to store data related to equipment in which a motor is installed, the data related to equipment being included in a signal sent via an electric communication circuit, and a degradation diagnosis apparatus configured to diagnose a degree of shaft degradation related to the rotation shaft constituting the equipment based on data related to a current flowing through the equipment, the data related to a current being stored in the storage device.

A degradation diagnosis method according to an embodiment of the present disclosure is a degradation diagnosing method of diagnosing progress of degradation in equipment in which a motor is installed, the method including: a dynamic eccentricity estimate process of estimating a degree of dynamic eccentricity of a rotation shaft included in the equipment, based on a current flowing through the motor, and a degradation diagnosis process of diagnosing a degree of shaft degradation related to the rotation shaft based on the result of estimation.

According to the degradation diagnosis apparatus according to an embodiment of the present disclosure, it is possible to make a high-precision diagnosis of the degree of shaft degradation related to the rotating shaft by estimating the degree of dynamic eccentricity based on the current flowing through the motor and diagnosing based on the results of estimation. Consequently, it is possible to improve the reliability of the equipment.

### BRIEF DESCRIPTION OF DRAWINGS

FIG. 1 is a diagram explaining an example of the configuration of the degradation diagnosis system SYS1 in Embodiment 1.

FIG. 2 is a diagram explaining an internal configuration example of a compressor 5 of Embodiment 1.

FIG. 3 is a diagram explaining the state between the main shaft 52 and the main bearing 57 when the compressor 5 of Embodiment 1 is driven.

FIG. 4 is a block diagram showing the configuration of the degradation diagnosis unit 100 in the controller 10 of Embodiment 1.

FIG. 5 is a block diagram showing the configuration of the static eccentricity estimating unit 110 in the degradation diagnosis unit 100 of Embodiment 1.

FIG. 6 is a block diagram showing the configuration of the dynamic eccentricity estimating unit 120 in the degradation diagnosis unit 100 of Embodiment 1.

FIG. 7 is a diagram showing U-phase current Iu and the envelope line Env of the U-phase current Iu.

FIG. 8 is a diagram of an example image expressing the degree of shaft degradation of dynamic eccentricity estimation in the dynamic eccentricity estimating unit 120 of Embodiment 1 by the frequency characteristic.

FIG. 9 is a diagram explaining the flow of degradation diagnosis processing in the degradation diagnosis unit 100 of Embodiment 1.

FIG. 10 is a diagram explaining the flow of a shaft degradation determination process performed by the shaft degradation diagnosis unit 130 of Embodiment 1.

FIG. 11 is a diagram explaining the threshold in the shaft degradation determination process performed by the shaft degradation diagnosis unit 130 of Embodiment 1.

FIG. 12 is a block diagram showing the configuration of the degradation diagnosis unit 100 and degradation estimation learning unit 200 in the controller 10 of Embodiment 2.

FIG. 13 is a diagram explaining the process flow in the degradation estimation learning unit 200 of Embodiment 2.

FIG. 14 is a diagram explaining the process flow in the inferring unit 125 of the dynamic eccentricity estimating unit 120 of Embodiment 2.

FIG. 15 is a block diagram showing the configuration of the shaft degradation diagnosis unit 130 of Embodiment 3.

FIG. 16 is a diagram explaining the threshold in the shaft degradation determination process performed by the shaft degradation diagnosis unit 130 of Embodiment 3.

FIG. 17 is a block diagram explaining an example of the configuration of the degradation diagnosis system SYS2 in Embodiment 4.

### DETAILED DESCRIPTION

The following will explain a degradation diagnosis apparatus, a degradation diagnosis system, a learning apparatus and a degradation diagnosis method pertaining to embodiments, with reference to the drawings. Here, in each drawing, a configuration to which the same sign is assigned is a configuration identical or equivalent to it, and it is common throughout the embodiments described below. Moreover, the forms of the constituent elements represented in all the embodiments described below are for illustration, and are not limited to the forms described below. Specifically, the combination of elements is not limited to the combination in each embodiment, and elements described in another embodiment can be applied to another embodiment. Furthermore, regarding the high and low of parameters such as pressure and temperature, it is not that the high and low are determined in relation to a particularly absolute value, but it is assumed to be relatively determined according to the state and operation of the device.

### Embodiment 1

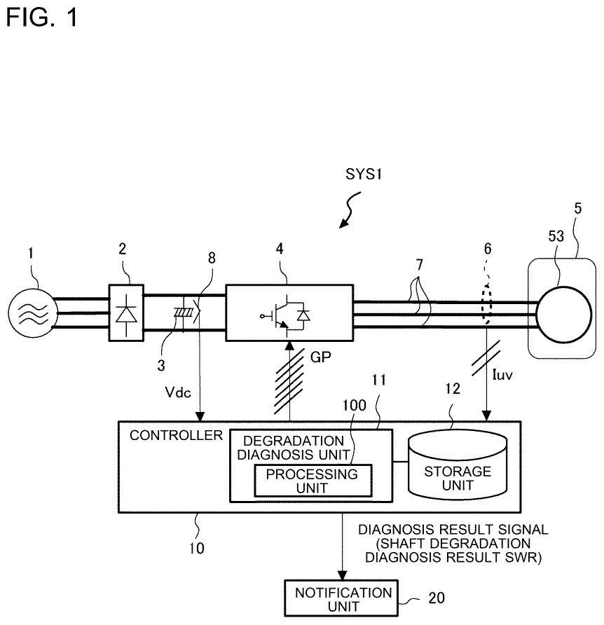

FIG. 1 is a diagram explaining an example of the configuration of the degradation diagnosis system SYS1 in Embodiment 1. The degradation diagnosis system SYS1 pertaining to Embodiment 1 will be explained with reference to figures such as FIG. 1. In the degradation diagnosis system SYS1 in Embodiment 1, as mentioned later, the controller 10 serves as the degradation diagnosis device and carries out the degradation diagnosis process for the equipment to be diagnosed. Here, the compressor 5, which has a motor 53 and is used in devices such as refrigeration cycle apparatuses, is the equipment to be diagnosed. The configuration of the compressor 5 will be described later.

The compressor 5 is driven at a predetermined driving frequency by configuration equipment that includes an AC power source 1, a rectifier circuit 2, an electrolytic capacitor 3, and an inverter circuit 4. The rectifier circuit 2 converts three-phase (U-phase, V-phase, and W-phase) AC power from the AC power source 1 into DC power. The electrolytic capacitor 3 smoothens the DC power coming from the rectifier circuit 2. Based on the gate pulse GP, which is a command from the controller 10, the inverter circuit 4 converts DC power from the rectifier circuit 2 into three-phase AC power based on the driving frequency and supplies this three-phase AC power to the compressor 5.

The current sensor 6 is installed midway in the wiring 7 that runs from the inverter circuit 4 to the compressor 5. The current sensor 6, based on the preset drive frequency, detects two phase currents out of the three-phase alternating current flowing from the inverter circuit 4 to the compressor 5. In this case, the current sensor 6, for example, detects the U-phase current Iu and the V-phase current Iv, and sends these as the current detection signal Iuv to the controller 10. The voltage sensor 8 detects the bus voltage. The voltage detected by the voltage sensor 8 is sent to the controller 10 as the voltage detection signal Vdc.

Furthermore, the controller 10 constitutes constituent equipment that drives the compressor 5. Based on the current detection signal Iuv related to the detection by the current sensor 6 and the voltage detection signal Vdc related to the detection by the voltage sensor 8, the controller 10 outputs a gate pulse GP to the inverter circuit 4 to control the operation of the compressor 5.

Here, the controller 10 has hardware such as a computer that executes various programs, implementing various processes such as control processing and degradation diagnosis process. The main processor in the hardware during the execution of various processes is a processing unit 11 such as CPU (Central Processing Unit) or FPGA (Field-Programmable Gate Array). The processing performed by the controller 10 is implemented by the processing unit 11 executing processes based on the program data stored in the storage unit 12. The storage unit 12 comprises a volatile storage device such as a Random Access Memory (RAM) that can temporarily store data, and a non-volatile auxiliary storage device such as flash memory that can store data long-term (both not shown). And as previously described, the storage unit 12 stores the program for the processing unit 11 to perform processing. And as mentioned above, the storage unit 12 stores the programs that the processing unit 11 needs to perform processing. In what follows, the processing and storage performed by the processing unit 11 and the storage unit 12 will be explained as being performed by the controller 10.

Here, specifically, the controller 10 in Embodiment 1 has a degradation diagnosis unit 100. Therefore, the controller 10 in Embodiment 1 functions as a degradation diagnosis apparatus. The degradation diagnosis unit 100, based on the current detection signal Iuv related to the detection by the current sensor 6, carries out a diagnosis process related to degradation, such as damage to the main bearing 57 concerning the relationship between the main shaft 52 and the main bearing 57 in the compressor 5, which will be described later. It then outputs a diagnosis result signal that includes the shaft degradation diagnosis result SWR. The structure of the processing function related to the degradation diagnosis unit 100 and the contents of the process and other details will be described later. And hereafter, the degradation related to the relationship between the main shaft 52 and the main bearing 57 will be referred to as shaft degradation.

The notification unit 20 is a device that provides notifications based on signals from the controller 10. In this case, the notification unit 20 has a display device, and it provides a display based on the diagnosis result signal including the shaft degradation diagnosis result SWR output by the degradation diagnosis unit 100, thereby notifying the user or maintenance crew of the degree of shaft degradation.

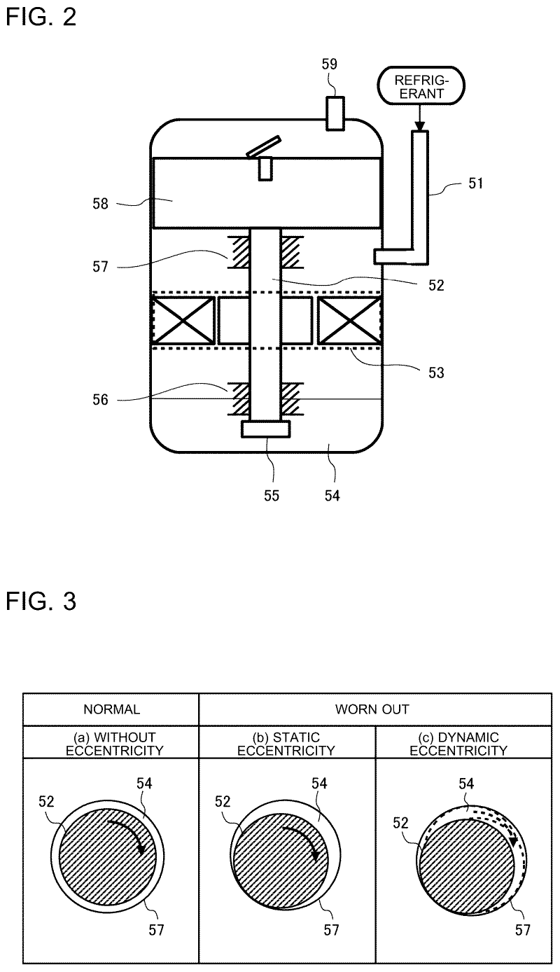

FIG. 2 is a diagram explaining an example of the internal configuration of the compressor 5 in Embodiment 1. As shown in FIG. 2, the compressor 5 includes a suction pipe 51, a main shaft 52, a motor 53, lubricant oil 54, an oil pump 55, a sub-bearing 56, a main bearing 57, a compression mechanism 58, and a discharge pipe 59. The compressor 5 is a device that forms a part of the refrigerant circuit in refrigeration cycle devices such as air conditioners. Also, in the compressor 5, the refrigerant is sucked in from the suction pipe 51 of the compressor 5 and is discharged from the discharge pipe 59.

The suction pipe 51 is a pipe for drawing low-temperature, low-pressure refrigerant into the interior of the compressor 5. Sensors such as pressure, temperature, and humidity sensors may be attached to the suction pipe 51 to measure the pressure, temperature, and humidity of the refrigerant flowing inside the pipe. Also, these sensors or similar devices can be attached to the pipes within the refrigerant circuit to estimate the pressure, temperature, and humidity of the refrigerant flowing inside the suction pipe 51.

The motor 53 is connected to a three-phase AC power line (not shown) and is driven according to the voltage applied from the inverter circuit 4. The main shaft 52, which is a rotation shaft, is connected to the motor 53. When the motor 53 drives the main shaft 52, it rotates, transmitting rotational energy, which is the driving power, to the compression mechanism 58. The lubricant oil 54 is accumulated at the bottom of the compressor 5 and is supplied by the oil pump 55 to the sub-bearing 56 and the main shaft 52, lubricating the sub-bearing 56 and the main shaft 52. As a way to verify the quantity of the lubricant oil 54, a liquid level sensor can be attached to the compressor 5 to detect the height of the oil surface of the lubricant oil and measure the quantity of the lubricant oil 54. The sub-bearing 56 and the main bearing 57 support the main shaft 52.

The discharge pipe 59 is a pipe for discharging high-temperature and high-pressure refrigerant, which has been compressed by the compression mechanism 58, to the outside of the compressor 5. Sensors such as a pressure sensor, temperature sensor, humidity sensor, may be attached to the discharge pipe 59 to detect the pressure, temperature, and humidity of the refrigerant flowing inside the pipe. In addition, these sensors or similar devices can be attached to the pipes inside an air-conditioning unit to estimate the pressure, temperature, humidity, etc., of the refrigerant flowing inside the discharge pipe 59.

FIG. 3 is a diagram explaining the state of the main shaft 52 and the main bearing 57 when the compressor 5 of Embodiment 1 is driven. Here, FIG. 3(a) is a cross-sectional view when the compressor 5 is being driven normally, showing a situation where the main shaft 52 and the main bearing 57 have a lubricated relationship. Moreover, FIG. 3(b) and FIG. 3(c) are cross-sectional views showing a situation in which there is a non-lubricated relationship between the main shaft 52 and the main bearing 57, indicating shaft degradation.

As shown in FIG. 3(a), when the compressor 5 is being driven normally, the space between the main shaft 52 and the main bearing 57 is filled with sufficient lubricant oil 54. And the main shaft 52 is smoothly rotating, maintaining a certain gap from the main bearing 57.

On the other hand, as shown in FIG. 3(b) and FIG. 3(c), when the compressor 5 degrades, the viscosity of the lubricant oil 54 may decrease due to the effects of temperature, aging, and other causes, making it impossible to maintain an oil film between the main shaft 52 and the main bearing 57. Therefore, the main shaft 52 and the main bearing 57 come into contact at certain points, and degradation of the main bearing 57 occurs at these points of contact. If the main shaft 52 continues to rotate in this state where the main bearing 57 has worn, the degradation on the main bearing 57 further worsens, and shaft degradation progresses. In such a scenario, the controller 10 could ultimately be forced to shut down (downtime) the compressor 5, potentially leading to a decrease in the operation rate of the compressor 5.

In this context, it is said that static eccentricity occurs, as indicated in FIG. 3(b), when the main shaft 52 continually rotates in an off-center situation at a certain position within the main bearing 57. On the other hand, as shown in FIG. 3(c), when the main shaft 52 continues to rotate while touching the inside of the main bearing 57 for each mechanical angle period, it is said that dynamic eccentricity has occurred. Both the static eccentricity indicated in FIG. 3(b) and dynamic eccentricity shown in FIG. 3(c) are affected by the installation environment and load state of the compressor 5, leading to an occurrence of either or both eccentricities simultaneously. This worsens shaft degradation and may potentially decrease the operating rate of the compressor 5.

From the above, by obtaining at least one of the static eccentricity shown in FIG. 3(b) and the dynamic eccentricity shown in FIG. 3(c), and employing measures based on the degree of eccentricity, the reliability of the compressor 5 and devices such as a refrigeration cycle apparatus equipped with the compressor 5 can be improved. Furthermore, a better service can be provided to users.

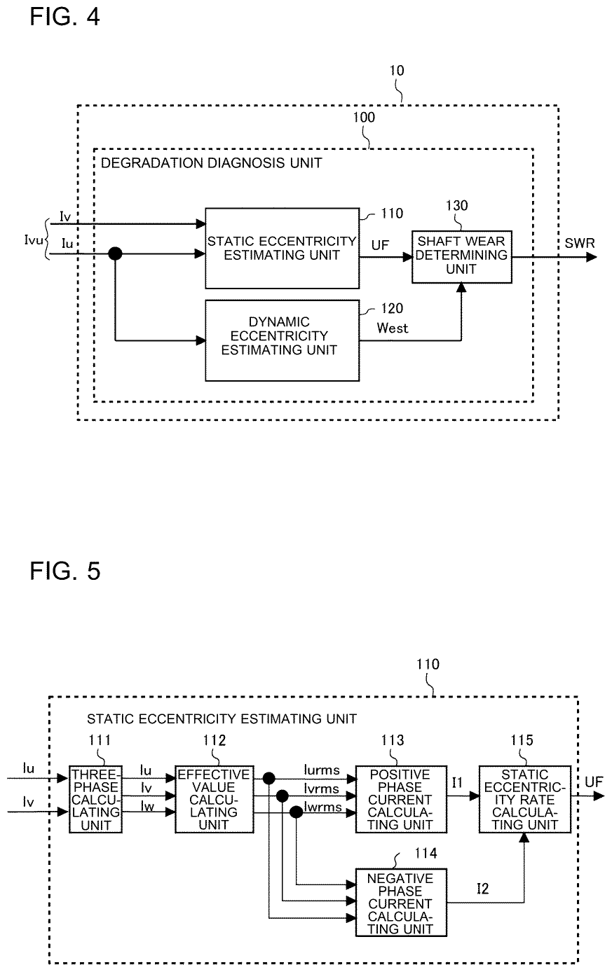

FIG. 4 is a block diagram showing the configuration of the degradation diagnosis unit 100 in the controller 10 of Embodiment 1. As previously described, the controller 10 functions as a degradation diagnosis device by having the degradation diagnosis unit 100. The degradation diagnosis unit 100 performs the degradation diagnosis process and outputs a diagnosis result signal that includes the shaft degradation diagnosis result SWR. The degradation diagnosis unit 100 in Embodiment 1 comprises a static eccentricity estimating unit 110, a dynamic eccentricity estimating unit 120, and a shaft degradation diagnosis unit 130.

The static eccentricity estimating unit 110 performs a static eccentricity estimation process, calculating the degree of static eccentricity from the U-phase current Iu and V-phase current Iv, and outputs, as the static eccentricity rate UF, the estimated result. Details about the static eccentricity estimating unit 110 will be explained later. Also, the dynamic eccentricity estimating unit 120 performs a dynamic eccentricity estimation process, calculating the degree of dynamic eccentricity from the U-phase current Iu, and outputs the estimated result as the dynamic eccentricity rate West. Details about the dynamic eccentricity estimating unit 120 will also be explained later. The shaft degradation diagnosis unit 130 then performs a degradation diagnosis process, diagnosing the degree of shaft degradation related to the main shaft 52 from the static eccentricity rate UF and the dynamic eccentricity rate West, and outputs a diagnosis result signal including the shaft degradation diagnosis result SWR to the notification unit 20.

FIG. 5 is a block diagram showing the configuration of the static eccentricity estimating unit 110 in the degradation diagnosis unit 100 according to Embodiment 1. FIG. 5 represents the processing content in the static eccentricity estimation process performed by the static eccentricity estimating unit 110, divided into parts. The static eccentricity estimating unit 110 includes a three-phase calculating unit 111, an effective value calculating unit 112, a positive phase current calculating unit 113, a negative phase current calculating unit 114, and a static eccentricity rate calculating unit 115.

The three-phase calculating unit 111 calculates the W-phase current Iw based on the formula (1), using the two-phase currents (namely, U-phase current Iu and V-phase current Iv) among the three-phase alternating current.

$$\begin{matrix}[ Math . 1 ] & \\ Iw = - Iu - Iv & ( 1 )\end{matrix}$$

The effective value calculating unit 112 calculates the effective values (U-phase effective value Iurms, V-phase effective value Ivrms, and W-phase effective value Iwrms) from the three-phase current (U-phase current Iu, V-phase current Iv, and W-phase current Iw) received from the three-phase calculating unit 111. Moreover, the positive phase current calculating unit 113 calculates the positive phase current I1 based on formulas (2) and (3).

$$\begin{matrix}[ Math . 2 ] & \\ I = \frac{( {I}_{urms} + {I}_{vrms} + {I}_{wrms} )}{2} & ( 2 )\end{matrix}$$

$$\begin{matrix}[ Math . 3 ] & \\ {I}_{1} = \sqrt{\frac{( {I}_{urms}^{2} + {I}_{vrms}^{2} + {I}_{wrms}^{2} )}{6} + \frac{2}{\sqrt{3}} \sqrt{I ( I - {I}_{urms} ) ( I - {I}_{vrms} ) ( ( I - {I}_{wrms} )}} & ( 3 )\end{matrix}$$

The negative phase current calculating unit 114 calculates the negative phase current I2 based on formulas (2) and (4).

$$\begin{matrix}[ Math . 4 ] & \\ {I}_{2} = \sqrt{\frac{( {I}_{urms}^{2} + {I}_{vrms}^{2} + {I}_{wrms}^{2} )}{6} - \frac{2}{\sqrt{3}} \sqrt{I ( I - {I}_{urms} ) ( I - {I}_{vrms} ) ( ( I - {I}_{wrms} )}} & ( 4 )\end{matrix}$$

The static eccentricity rate calculating unit 115 calculates the static eccentricity rate UF based on the positive phase current I1 and the negative phase current I2, according to formula (5).

$$\begin{matrix}[ Math . 5 ] & \\ UF = 100 \frac{{I}_{2}}{{I}_{1}} & ( 5 )\end{matrix}$$

From formulas (3), (4), and (5), it is apparent that the higher the discrepancy among the individual effective values (the U-phase effective value Iurms, V-phase effective value Ivrms and W-phase effective value Ivrms), the higher the value of the static eccentricity rate UF.

As described above, the static eccentricity estimating unit 110 calculates the static eccentricity rate UF from the ratio of the positive phase current I1 and the negative phase current I2. Therefore, the static eccentricity estimating unit 110 can estimate the degree of shaft degradation for various models. By estimating the degree of shaft degradation with the static eccentricity rate UF, the reliability of the compressor 5 and refrigeration cycle devices equipped with the compressor 5 can be improved. Hence, a better service can be provided to the users.

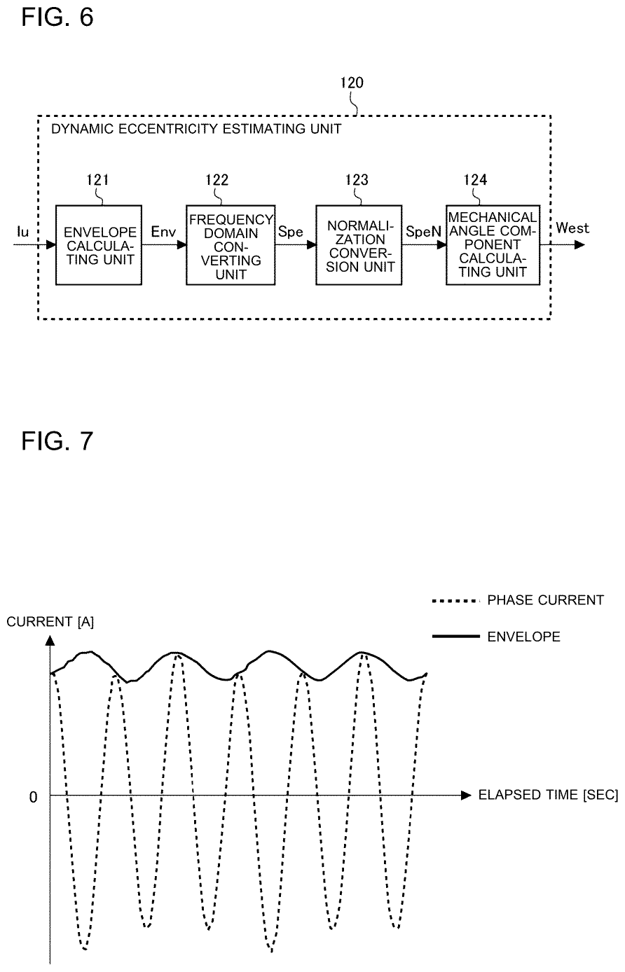

FIG. 6 is a block diagram showing the configuration of the dynamic eccentricity estimating unit 120 in the degradation diagnosis unit 100 of Embodiment 1. The divisions shown in FIG. 6 detail the operations performed in the dynamic eccentricity estimation process performed by the dynamic eccentricity estimating unit 120. The dynamic eccentricity determining unit 120 includes an envelope calculating unit 121, a frequency domain converting unit 122, a normalization converting unit 123, and a mechanical angle component extracting unit 124.

FIG. 7 is a diagram showing the U-phase current Iu and the envelope Env of U-phase current Iu. In FIG. 7, the horizontal axis represents elapsed time, and the vertical axis represents current. Furthermore, in FIG. 7, the solid line represents the envelope Env, and the dotted line represents the phase current. Based on FIG. 7, the processing in the envelope calculating unit 121 will be explained. The envelope calculating unit 121 performs envelope processing to calculate the envelope Env of the U-phase current Iu. By applying envelope processing and calculating with the envelope calculating unit 121, it is possible to obtain an envelope Env that follows the positive peak value of the phase current. It is difficult to detect a mechanical angle component due to a small dynamic eccentricity from an alternating current waveform like a phase current. Therefore, by using the envelope Env obtained by the envelope processing applied by the envelope calculating unit 121, large pulsations can be generated to make it easier to extract the mechanical angle components.

The frequency domain converting unit 122 executes a frequency domain transformation process for the envelope Env and generates a spectrum Spe according to the frequency. Furthermore, the normalization converting unit 123 executes a normalization process for the spectrum Spe generated by the frequency domain converting unit 122 and generates a normalized spectrum SpeN. The mechanical angle component extracting unit 124 extracts the mechanical angle component of the compressor 5 from the normalized spectrum SpeN and outputs a dynamic eccentricity rate West, which indicates the degree of dynamic eccentricity.

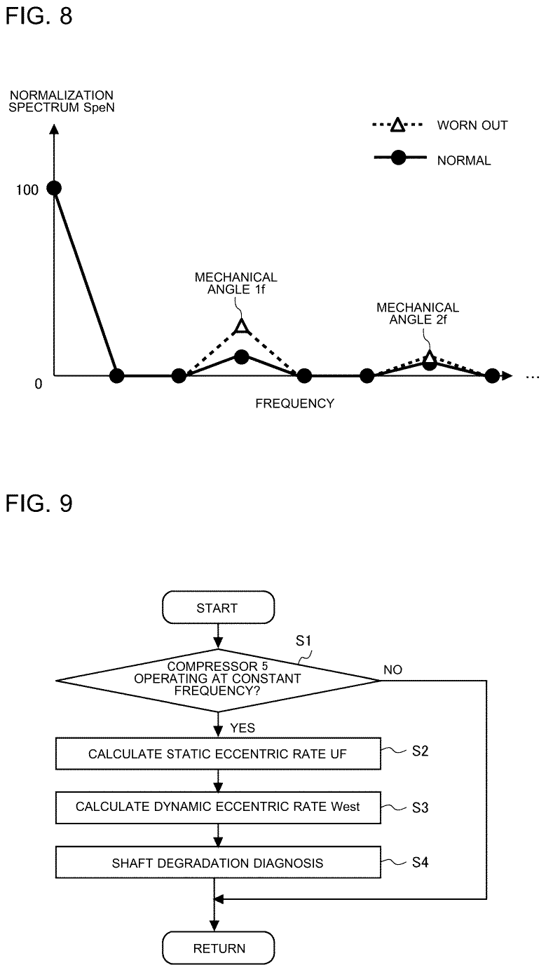

FIG. 8 is an illustration of an example image expressing the degree of shaft degradation of dynamic eccentricity estimation in the dynamic eccentricity estimating unit 120 of Embodiment 1 by the frequency characteristic. In FIG. 8, the horizontal axis represents the frequency, and the vertical axis represents the normalized spectrum SpeN. Furthermore, in FIG. 8, the solid lines each represent the normalized spectrum SpeN of a normal compressor 5 where shaft degradation has not occurred, and the dotted lines each represent the normalized spectrum SpeN of a compressor 5 where shaft degradation is progressing.

In the waveform of the envelope Env in FIG. 7 obtained by the envelope calculating unit 121 performing envelope processing, the pulsation of mechanical angle due to shaft degradation is superimposed on the direct current component. Therefore, when the frequency domain converting unit 122 performs frequency domain conversion, a peak of the spectrum Spe occurs in the zeroth-order component (DC component) of the frequency. When the normalization converting unit 123 divides the spectrum Spe at each frequency by the peak value of the spectrum Spe, as shown in FIG. 8, the zeroth-order component becomes 100, and the normalized spectrum SpeN can be obtained. By comparing, as shown in FIG. 8, the normalized spectrum SpeN of a properly-working compressor 5 and the normalized spectrum SpeN of a compressor 5 on which shaft degradation is progressing, there is a difference in the spectral value with respect to the mechanical angle frequency in the mechanical angle. By focusing on the mechanical angle frequency, the mechanical angle component extracting unit 124 outputs the dynamic eccentricity rate West. For instance, by focusing on the component of the mechanical angle 1f of the mechanical angle frequency, the degree of dynamic eccentricity can be detected. Although the mechanical angle component extracting unit 124 outputs the dynamic eccentricity rate West by focusing on the components of the mechanical angle 1f as an example, this is not limiting. For example, the mechanical angle component extracting unit 124 may output the dynamic eccentricity rate West by focusing on other mechanical angle components, such as a mechanical angle 2f component.

As described above, the dynamic eccentricity estimating unit 120 calculates the dynamic eccentricity rate West from the mechanical angle frequency. By estimating the degree of shaft degradation with the dynamic eccentricity rate West, the reliability of the compressor 5 and the refrigeration cycle apparatus equipped with the compressor 5 can be improved. Furthermore, a better service can be provided to users.

FIG. 9 is a diagram explaining the flow of the degradation diagnosis process of the degradation diagnosis unit 100 in Embodiment 1. The degradation diagnosis unit 100 repeats the degradation diagnosis process at regular intervals. The degradation diagnosis unit 100 determines whether the compressor 5 is being driven at a constant speed (Step S1). If the degradation diagnosis unit 100 determines that the compressor 5 is not being driven at a constant speed, it repeats the process. Here, being driven at a constant speed means that the motor 53 is being driven at the same rotation speed. Regarding whether the compressor 5 is being driven at a constant speed or not, for example, the degradation diagnosis unit 100 calculates the current phase of the U-phase current Iu for each cycle, and if the change in phase is almost none for each cycle, it is determined that the compressor 5 is being driven at a constant speed. Also, for example, if the controller 10 is estimating the rotation speed of the motor 53, the degradation diagnosis unit 100 may determine whether it is being driven at a constant speed based on the rotation speed estimated by the controller 10. When the compressor 5 is driven at a constant speed, the estimation accuracy of the static eccentricity rate UF and the dynamic eccentricity rate West is better compared to when it is being driven with acceleration and deceleration. Therefore, it is possible to improve the reliability of the system and provide better service to the user.

On the other hand, when the degradation diagnosis unit 100 determines that the compressor 5 is operating consistently, the static eccentricity estimating unit 110 performs the static eccentricity estimation process as previously described and calculates the static eccentricity rate UF (Step S2). Moreover, the dynamic eccentricity estimating unit 120 performs the dynamic eccentricity estimation process as previously described and calculates the dynamic eccentricity rate West (Step S3). Then, the shaft degradation diagnosis unit 130 executes the shaft degradation diagnosis based on the static eccentricity rate UF calculated by the static eccentricity estimating unit 110 and the dynamic eccentricity rate West calculated by the dynamic eccentricity estimating unit 120 (Step S4).

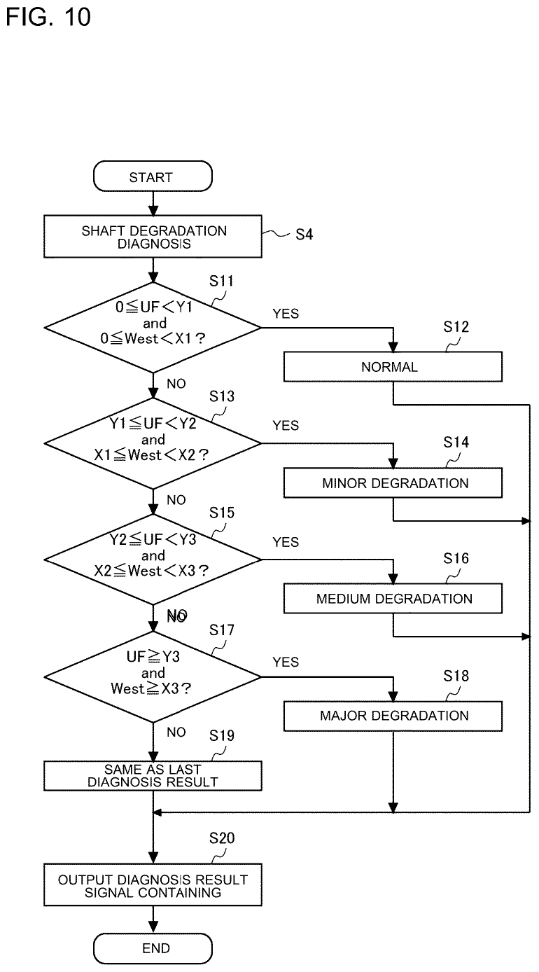

FIG. 10 is a diagram explaining the flow of the shaft degradation determination process performed by the shaft degradation diagnosis unit 130 in Embodiment 1. The shaft degradation diagnosis unit 130 determines in the diagnosis of shaft degradation (in step S4), whether the static eccentricity rate UF is equal to or greater than 0 and less than Y1, and the dynamic eccentricity rate West is equal to or greater than 0 and less than X1 (hereinafter referred to as “condition 1”) (step S11). If the shaft degradation diagnosis unit 130 determines that condition 1 is satisfied, it determines this as “normal” (step S12). Then, it outputs a diagnosis result signal including a shaft degradation diagnosis result SWR indicating “normal” to the notification unit 20 (step S20). The notification unit 20 displays a notification indicating normality based on the diagnosis result signal.

On the other hand, when the shaft degradation diagnosis unit 130 determines that condition 1 is not being met, it further determines whether the static eccentricity rate UF is equal to or greater than Y1 and less than Y2, and the dynamic eccentricity rate West is equal to or greater than X1 and less than X2 (hereinafter referred to as “condition 2”) (Step S13).

If the shaft degradation diagnosis unit 130 determines that Condition 2 is satisfied, it deems the status as “minor degradation” (Step S14). Then, it outputs a diagnosis result signal that includes the shaft degradation diagnosis result SWR indicating “minor degradation” to the notification unit 20 (Step S20). The notification unit 20 displays a notification indicating minor degradation based on the diagnosis result signal.

When the shaft degradation diagnosis unit 130 determines that condition 2 is not satisfied, it further determines whether the static eccentricity rate UF is equal to or greater than Y2 and less than Y3, and whether the dynamic eccentricity rate West is equal to or greater than X2 and less than X3 (hereinafter referred to as condition 3) (Step S15). If the shaft degradation diagnosis unit 130 determines that condition 3 is satisfied, it deems the status as “medium degradation” (Step S16). It then outputs a diagnosis result signal, which includes the shaft degradation diagnosis result SWR indicating “medium degradation”, to the notification unit 20 (Step S20). The notification unit 20 provides a display indicating medium degradation based on the diagnosis result signal.

When the shaft degradation diagnosis unit 130 determines that condition 3 is not satisfied, it further determines whether the static eccentricity rate UF is equal to or greater than Y3, and whether the dynamic eccentricity rate West is equal to or greater than X3 (hereinafter referred to as condition 4) (Step S17). When the shaft degradation diagnosis unit 130 determines that condition 4 is satisfied, it deems it as “major degradation” (Step S18). Then, it outputs a diagnosis result signal including the shaft degradation diagnosis result SWR, which indicates “major degradation”, to the Notification Unit 20 (Step S20). Based on the diagnosis result signal, the notification unit 20 displays that there is major degradation.

If the shaft degradation diagnosis unit 130 determines that condition 3 is not satisfied, it determines that the result is the same as the previous diagnosis result (step S19). Then, it outputs a diagnosis result signal including the same shaft degradation diagnosis result SWR as the previous one to the notification unit 20 (step S20). The notification unit 20 then provides a display similar to the previous diagnosis based on the diagnosis result signal. Here, it should be noted that the shaft degradation progresses gradually. Therefore, if the shaft degradation diagnosis unit 130 compares the previous diagnosis result with the current diagnosis result and determines that the degree of shaft degradation has worsened in the current diagnosis result, it could output a diagnosis result signal based on the shaft degradation diagnosis result SWR, which indicates deterioration, to the notification unit 20.

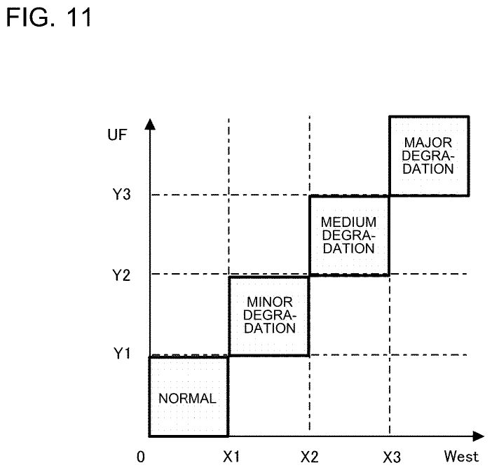

FIG. 11 is a diagram explaining the threshold in the shaft degradation determination process performed by the shaft degradation diagnosis unit 130 of Embodiment 1. As shown in FIG. 11, in the shaft degradation determination process, three thresholds (0<Y1<Y2<Y3) are set for the static eccentricity rate UF. Similarly, three thresholds (0<X1<X2<X3) are set for the dynamic eccentricity rate West. The shaft degradation diagnosis unit 130 determines the degree of shaft degradation based on these thresholds for both the static eccentricity rate UF and the dynamic eccentricity rate West, conducts a degradation diagnosis based on this determination, and outputs a diagnosis result signal, based on the shaft degradation diagnosis result SWR, to the notification unit 20.

Although FIG. 11 shows the thresholds set at equal intervals, they are not limited to these intervals. For example, thresholds can be set at intervals other than equal ones in advance, depending on the user's installation environment. Also, in Embodiment 1, three thresholds are set for both the static eccentricity rate UF and the dynamic eccentricity rate West, dividing them into four categories: the shaft degradation diagnosis result SWR is identified as one of four degradation patterns: “normal,” “minor degradation,” “medium degradation,” and “major degradation.” However, they are not limited to these categories. For example, there could be just two degradation patterns: “normal” and “degraded.” Thus, it is not necessary to limit the number of thresholds for the static eccentricity rate UF and the dynamic eccentricity rate West to three and the number of divisions to four. Furthermore, although not particularly limited, if the static eccentricity rate UF or the dynamic eccentricity rate West cannot be calculated, and neither of the results of estimation can be obtained, a diagnosis result signal including the same shaft degradation diagnosis result SWR as the previous one may be output to the notification unit 20.

As described above, in the degradation diagnosis system SYS1 according to Embodiment 1, the degradation diagnosis unit 100 of the controller 10, which operates as a degradation diagnosis device, calculates the static eccentricity rate UF and dynamic eccentricity rate West based on the U-phase current Iu and V-phase current Iv included in the current detection signal Iuv. Further, the degradation diagnosis unit 100 performs a shaft degradation diagnosis based on the static eccentricity rate UF and dynamic eccentricity rate West, and outputs a diagnosis result signal containing the shaft degradation diagnosis result SWR to the notification unit 20. By performing a shaft degradation diagnosis based on the degree of the two eccentricities of static eccentricity and dynamic eccentricity caused by the main shaft 52, the degradation diagnosis unit 100 can improve the reliability of the equipment. Therefore, a better service can be provided to users.

In addition, the degradation diagnosis unit 100 in Embodiment 1 includes a static eccentricity estimating unit 110. The static eccentricity estimating unit 110 has a static eccentricity rate calculating unit 115, which calculates the ratio of the positive phase current I1, calculated by the positive phase current calculating unit 113, and the negative-phase current I2, calculated by the negative-phase current calculating unit 114, as the static eccentricity rate UF representing the degree of static eccentricity. This makes it possible to estimate a more accurate static eccentricity rate UF.

Furthermore, in Embodiment 1, the degradation diagnosis unit 100 includes a dynamic eccentricity estimating unit 120, including an envelope calculating unit 121 that calculates an envelope line Env for the phase current. Through the calculation of the envelope line Env, it is possible to obtain an emphasized alternating current waveform in comparison to the alternating current waveform caused by the phase current. Moreover, the dynamic eccentricity estimating unit 120 includes a mechanical angle component calculating unit 124 that estimates and calculates the dynamic eccentricity rate West, which represents the degree of dynamic eccentricity, based on the mechanical angle components. Therefore, based on the mechanical angle derived from the emphasized alternating current waveform, it is possible to estimate a more precise dynamic eccentricity rate West.

In the degradation diagnosis unit 100 according to Embodiment 1, it is determined that the compressor 5 is driven at a constant speed, and diagnostic processing is performed based on the U-phase current Iu and V-phase current Iv contained in the current detection signal Iuv when the drive is in a stable state. As a result, it is possible to diagnose shaft degradation more accurately.

### Embodiment 2

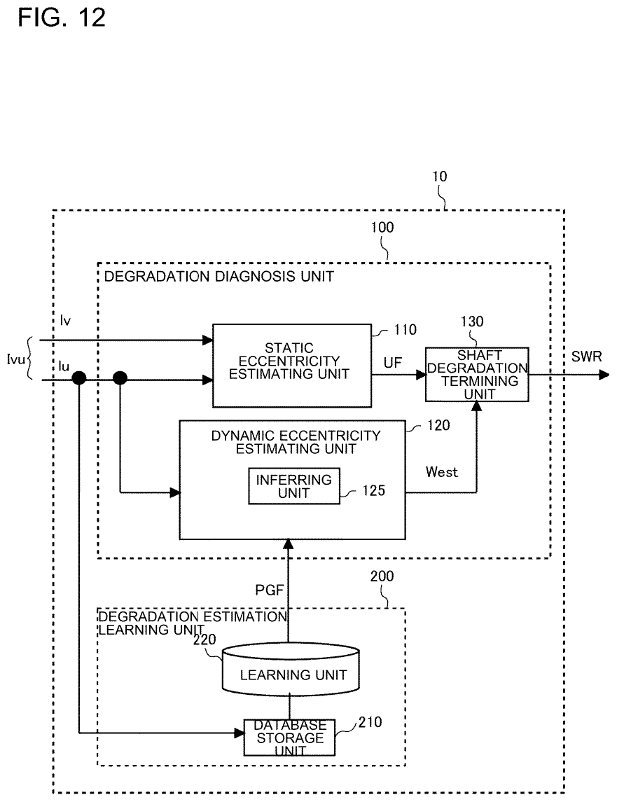

FIG. 12 is a block diagram showing the configuration of the degradation diagnosis unit 100 and degradation estimation learning unit 200 in the controller 10 of Embodiment 2. The controller 10 in Embodiment 2 has, in addition to the degradation diagnosis unit 100, a degradation estimation learning unit 200. The degradation estimation learning unit 200 conducts machine learning using the U-phase current Iu of the compressor 5, and creates a trained model for the dynamic eccentricity estimating unit 120 to obtain results of estimation. Therefore, in Embodiment 2, the controller 10 serves as a degradation estimation learning device, performing processes related to learning.

The degradation estimation learning unit 200 has a learning unit 210 and a database storage unit 220. The learning unit 210 performs a learning process using machine learning and generates data related to the constructed learned model as a pattern generation function PGF. The database storage unit 220 stores the pattern generation function PGF.

Also, in Embodiment 2, the degradation diagnosis unit 100 has a different configuration in the dynamic eccentricity estimating unit 120. The dynamic eccentricity estimating unit 120 in Embodiment 2 has an inferring unit 125. The inferring unit 125 in Embodiment 2 uses the pattern generation function PGF stored in the database storage unit 220 to obtain the dynamic eccentricity rate West. In Embodiment 2, the dynamic eccentricity estimating unit 120 uses the U-phase current Iu as input data, and uses the dynamic eccentricity rate West as output data.

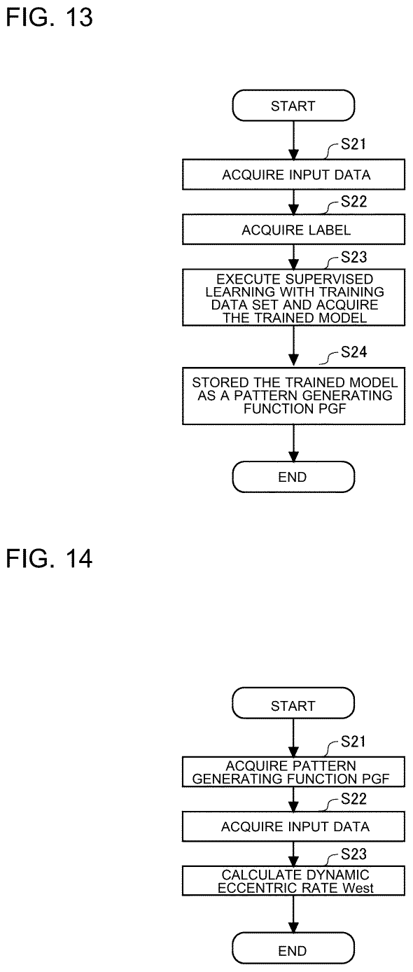

FIG. 13 is a diagram explaining the process flow in the degradation estimation learning unit 200 of Embodiment 2. Here, the processing procedure explained below is an example of a learning method. Therefore, the order of each process performed by the degradation estimation learning unit 200 can be changed as much as possible. Also, depending on the content of the processing, omission, replacement or addition of the processing can be done as appropriate.

The degradation estimation learning unit 200 acquires the U-phase current Iu of the compressor 5 as input data (Step S21). When the learning unit 210 performs a learning process, the controller 10 preemptively acquires the U-phase current Iu when driving the motor 53, which is already in a state where the main shaft 52 has degraded. This allows the acquisition of the U-phase current Iu for the amount of degradation of the main shaft 52. Here, while the input data is the U-phase current Iu, the V-phase current Iv may also serve as input data.

Also, the learning unit 210 acquires a known amount of degradation as a label (step S22). Here, the known amount of degradation refers to, for example, the amount by which the main shaft 52 of the compressor 5 has degraded due to wear from a normal state (for example, 50 μm, 100 μm, or 150 μm etc.).

The learning unit 210 acquires a pair of data (hereafter referred to as “set of teacher data”), which consists of input data obtained in step S21 and a label obtained in step S22 (step S23). Then, the learning unit 210 executes machine learning. The learning unit 210 builds a trained model by executing machine learning based on the set of teacher data. As a result, the learning unit 210 can associate the degree of degradation in the dynamic eccentricity of the compressor 5 based on the amount of degradation with the phase current.

In Embodiment 2, the machine learning conducted by the learning unit 210, targeting the compressor 5, is supervised learning through a neural network built by combining perceptrons. Specifically, the learning unit 210 feeds the neural network with a set of teacher data composed of input data indicating the phase current condition and labels according to the degradation state of the compressor 5. Then, while changing the weight values for each perceptron to make the output of the neural network the same as the labels, the learning unit 210 repeatedly carries out learning processes. During the learning process performed by learning unit 210, the values of weights are adjusted to reduce the error of each perceptron's output by repetitively executing a process called backpropagation (error backpropagation method).

As such, the learning unit 210 performs a process to learn the characteristics of a set of teacher data and inductively acquires a trained model for estimating results from input data. This allows the learning unit 210 to carry out supervised learning and, as described above, make adjustments to the weight values so as to eliminate errors between the label and output data.

Thus, the learning unit 210 acquires, as a result of supervised learning, a trained model for determining the degree of dynamic eccentricity from the phase current. The learning unit 210 then saves and preserves the data related to the trained model, constructed through supervised learning, to the database storage unit 220 as a pattern generating function (PGF) and preserves it (Step S24). Thus, through supervised learning, the learning unit 210 obtains a trained model to determine the degree of dynamic eccentricity from the phase current as a learning result. The pattern generating function (PGF) saved in the database storage unit 220 is utilized, as will be described later, when the inferring unit 125 performs the inference processing.

Here, the learning unit 210 may periodically perform the process from step S21 to step S24 to update the pattern generation function PGF. Also, the learning unit 210 may execute the process from step S21 to step S24 each time the degradation state of the compressor 5 changes, to update the pattern generation function PGF. Furthermore, although the learning unit 210 has saved the pattern generation function PGF that uses U-phase current Iu as the input data, it may generate the degradation degree based on data regarding other currents. For instance, the learning unit 210 can construct a learned model from at least one type of data based on information relating to the current, such as the likelihood, skewness, and harmonics of the current, and save it as the pattern generation function PGF. Moreover, without any particular limitation, the learning unit 210 can have a neural network with multiple layers and perform machine learning through so-called deep learning, utilizing a neural network with multiple layers (deep neural network learning).

FIG. 14 is a diagram explaining the process flow in the inferring unit 125 of the dynamic eccentricity estimating unit 120 of Embodiment 2. The inferring unit 125 estimates the dynamic eccentricity rate West from the inputted U-phase current Iu. The inferring unit 125 acquires the pattern generation function PGF stored in the database storage unit 220 (step S31). Also, the inferring unit 125 acquires the U-phase current Iu sent from the current sensor 6 as input data (step S32). Then, the inferring unit 125 inputs the data of the U-phase current Iu into the pattern generation function PGF, and calculates the dynamic eccentricity rate West at the main shaft 52 of the compressor 5.

As described above, in Embodiment 2, the controller 10 includes a degradation estimation learning unit 200. The degradation estimation learning unit 200 stores a trained model obtained by machine learning based on phase current performed by the learning unit 210, as a pattern generation function (PGF), in the database storage unit 220. Consequently, it becomes possible to estimate the dynamic eccentricity rate West, based on the actual phase current. The inferring unit 125 of the dynamic eccentricity estimating unit 120 then estimates the dynamic eccentricity rate West based on the phase current and the pattern generation function (PGF). Therefore, the dynamic eccentricity rate West can be estimated and calculated with higher precision. As a result, the diagnosis of shaft degradation can be performed more accurately, leading to an improvement in the reliability of the equipment.

### Embodiment 3

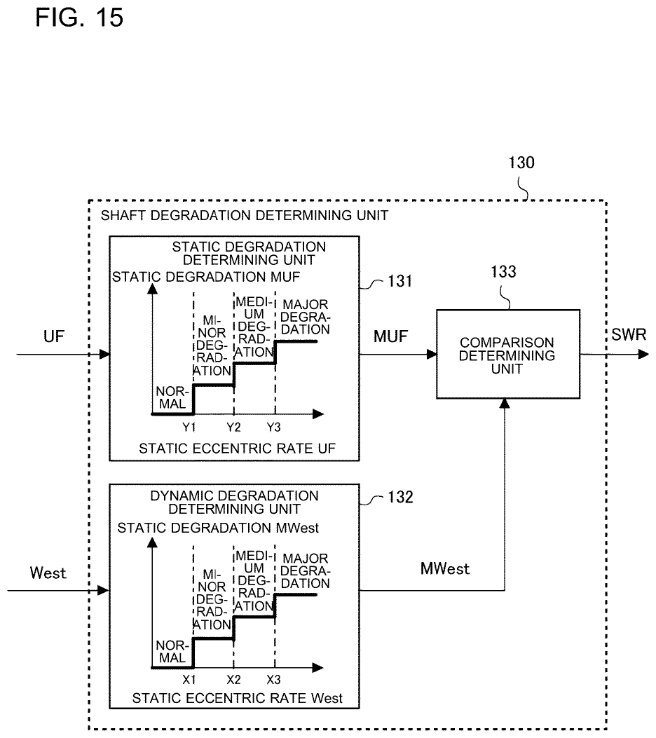

FIG. 15 is a block diagram showing the configuration of the shaft degradation diagnosis unit 130 in Embodiment 3. The degradation diagnosis unit 100 in Embodiment 3 performs processing that differs from that performed by the shaft degradation diagnosis unit 130 in Embodiment 1. FIG. 15 shows the processing content performed by the shaft degradation diagnosis unit 130 separated into different parts. The shaft degradation diagnosis unit 130 in Embodiment 3 comprises a static degradation determining unit 131, a dynamic degradation determining unit 132, and a comparison determining unit 133.

The static degradation determining unit 131 determines the static degradation degree (MUF) based on the static eccentricity rate (UF) calculated by the static eccentricity estimating unit 110. For example, the static degradation determining unit 131 compares the static eccentricity rate UF with the pre-set thresholds Y1, Y2, and Y3, and determines any one of “normal”, “minor degradation”, “medium degradation”, and “major degradation” as the static degradation degree MUF. Here, the magnitude relationship between the thresholds for the static eccentricity rate UF is set as 0<Y1<Y2<Y3. The static degradation determining unit 131 determines it as “normal” if the static eccentricity rate UF is equal to or greater than 0 and less than Y1. Additionally, the static degradation determining unit 131 determines it as “minor degradation” if the static eccentricity rate UF is equal to or greater than Y1 and less than Y2. Moreover, the static degradation determining unit 131 determines it as “medium degradation” if the static eccentricity rate UF is equal to or greater than Y2 and less than Y3. Finally, the static degradation determining unit 131 determines it as “major degradation” if the static eccentricity rate UF is equal to or more than Y3.

The dynamic deterioration determining unit 132 determines the degree of dynamic deterioration MWest based on the dynamic eccentricity rate West calculated by the dynamic eccentricity estimating unit 120. For instance, the dynamic degradation determining unit 132 compares thresholds X1, X2 and X3 against the dynamic eccentricity rate West, and determines any one of as “normal”, “minor degradation”, “medium degradation” or “major degradation” as the dynamic degradation degree MWest.

Here, the magnitude relation between the thresholds for the dynamic eccentricity rate West is set as 0<X1<X2<X3. If the dynamic eccentricity rate West is equal to or greater than 0 and less than X1, the dynamic degradation determining unit 132 determines it as “normal”. Additionally, if the dynamic eccentricity rate West is equal to or greater than X1 and less than X2, the dynamic degradation determining unit 132 determines it as “minor degradation”. Furthermore, if the dynamic eccentricity rate West is equal to or greater than X2 and less than X3, the dynamic degradation determining unit 132 determines it as “medium degradation”. Lastly, if the dynamic eccentricity rate West is equal to or greater than X3, the dynamic degradation determining unit 132 determines it as “major degradation”.

The comparison determining unit 133 outputs the shaft degradation diagnosis result SWR based on the static degradation degree MUF determined by the static degradation determining unit 131 and the dynamic degradation degree MWest determined by the dynamic degradation determining unit 132. The comparison determining unit 133 compares the static degradation degree MUF with the dynamic degradation degree MWest and outputs the higher degree of degradation as the shaft degradation diagnosis result SWR. If the degrees of degradation determined by the static degradation degree MUF and the dynamic degradation degree MWest are equal, the comparison determining unit 133 outputs this degradation degree as the shaft degradation diagnosis result SWR. For example, if the static degradation degree MUF is “normal” and the dynamic degradation degree MWest is “minor degradation”, the comparison determining unit 133 outputs “minor degradation” as the shaft degradation diagnosis result SWR.

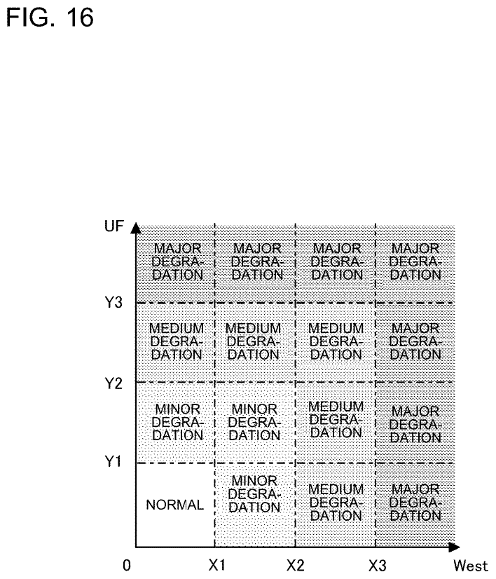

FIG. 16 is a diagram explaining the threshold in the shaft degradation determining processing performed by the shaft degradation diagnosis unit 130 in Embodiment 3. As shown in FIG. 16, three thresholds (0<Y1<Y2<Y3) are set for the static eccentricity rate UF and three thresholds (0<X1<X2<X3) are also set for the dynamic eccentricity rate West. The comparison determining unit 133 determines each degree of shaft degradation in the static eccentricity rate UF and the dynamic eccentricity rate West based on these thresholds. Then, based on the determination, the comparison determining unit 133 performs the diagnosis of shaft degradation of the higher degree of shaft degradation and outputs a diagnosis result signal based on the shaft degradation diagnosis result SWR to the notification unit 20.

In FIG. 16, while the respective thresholds are set at equal intervals, such a setting is not limited to this. For example, thresholds can be set at intervals other than equal ones in advance depending on the user's installation environment. Moreover, in Embodiment 3, three thresholds are set for each of the static eccentricity rate UF and the dynamic eccentricity rate West to divide into four categories, and the shaft degradation diagnosis result SWR is composed of the four degradation patterns: “normal”, “minor degradation”, “medium degradation”, and “major degradation”. However, it is not limited to this. For example, it could be categorized into two degradation patterns: “normal” and “degraded”. In addition, if the static eccentricity rate UF or the dynamic eccentricity rate West cannot be calculated, and results of estimation could not be obtained for either, the shaft degradation diagnosis unit 130 may perform a diagnosis based on the eccentricity rate for which results of estimation are obtained, and output the diagnosis result signal, based on the shaft degradation diagnosis result SWR, to the notification unit 20.

As described above, in Embodiment 3, the comparison determining unit 133 in the shaft degradation diagnosis unit 130 of the degradation diagnosis unit 100 compares the static degradation degree MUF determined by the static degradation determining unit 131 with the dynamic degradation degree MWest determined by the dynamic degradation determining unit 132. Then, the shaft degradation diagnosis unit 130 outputs to the notification unit 20 a result signal with the larger of the static degradation degree MUF and dynamic degradation degree MWest as the shaft degradation diagnosis result SWR. Therefore, even if one of static eccentricity or dynamic eccentricity is skewed, it is possible to perform a high-precision diagnosis of shaft degradation, thereby improving the reliability of the device. As a result, a better service can be provided to users.

### Embodiment 4

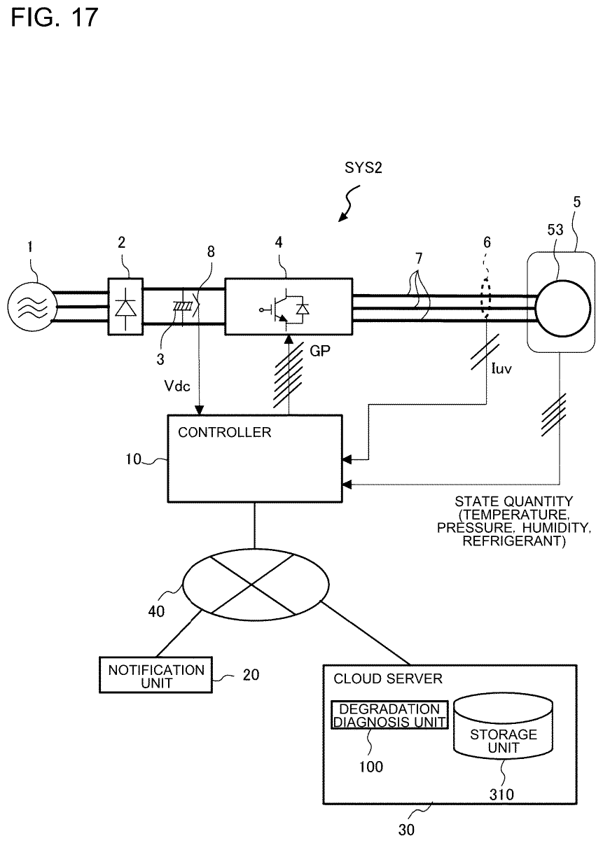

FIG. 17 is a block diagram illustrating an example configuration of the degradation diagnosis system SYS2 in Embodiment 4. The degradation diagnosis system SYS2 in Embodiment 4 has a different installation location for the degradation diagnosis unit 100 compared to the degradation diagnosis system SYS1 in Embodiment 1. Specifically, in the degradation diagnosis system SYS2 of Embodiment 4, the degradation diagnosis unit 100 is provided in a cloud server 30. Therefore, in Embodiment 4, the cloud server 30 functions as a degradation diagnosis apparatus. The cloud server 30, for example, is a device that performs processing such as cloud storage in cloud services. The cloud server 30 has a degradation diagnosis unit 100 and a storage unit 310.

The storage unit 310 includes recording equipment such as non-volatile auxiliary storage devices, including flash memory, that can store data over the long term, and it records data related to the state quantity of the compressor 5. The data related to the state quantity of the compressor 5 refers to data regarding the temperature, internal pressure, humidity, and refrigerant of the compressor 5, which is obtained based on signals from various sensors attached to the compressor 5. In addition, data about the phase current supplied to the compressor 5 is also included in the data related to the state quantity of the compressor 5. The data related to the state quantity of the compressor 5 is included in the signal sent from the controller 10 via the electric communication line 40.

The degradation diagnosis unit 100, based on the data related to the state quantity of the compressor 5 recorded by the storage unit 310, carries out the shaft degradation diagnosis process as explained in Embodiments 1 to 3, and outputs a signal that includes the shaft degradation diagnosis result SWR to the notification unit 20.

As described above, in the degradation diagnosis system SYS2 according to Embodiment 4, the cloud server 30 includes a degradation diagnosis unit 100, which serves as a degradation diagnosis device. Signals containing data relevant to the state quantity of the compressor 5, the device to be diagnosed for degradation, are sent from the controller 10 that controls the compressor 5 to the cloud server 30 via the electric communication circuit 40. Then, based on the phase current included in the sent signal, the degradation diagnosis unit 100 in the cloud server 30 diagnoses shaft degradation and outputs a signal containing the shaft degradation diagnosis result SWR to the notification unit 20. Therefore, it is possible to improve the reliability of the compressor 5 and refrigeration cycle devices equipped with the compressor 5. By also considering the user's usage environment, shaft wear can be diagnosed, thereby providing a better service to the user.

Here, although the cloud server 30 is explained as having the degradation diagnosis unit 100, it is not limited to this. For example, the cloud server 30 may have the degradation estimation learning unit 200 explained in Embodiment 2. In this case, the cloud server 30 acts as a degradation estimation learning device.

In this context, it has been mentioned that the cloud server 30 is equipped with the degradation diagnosis unit 100 and the storage unit 310. However, it is not limited to this. It is acceptable to use separate devices for degradation diagnosis and storage and connect them through an electrical communication circuit 40 to establish a system.

### Embodiment 5

In Embodiments 1 to 4 described above, we described a compressor 5, which is a piece of equipment with a rotating shaft, as the equipment subject to degradation diagnosis. However, it is not limited to this. This can be applied to pieces of equipment that have a motor 53 that turns a rotating shaft by current. It can also be applied to equipment like generators.

Embodiments 1 to 4 described above are illustrative and not limiting. Any changes within the scope and interpretation indicated by the claims are intended to be included within the disclosures. Elements described in each embodiment are intended to be performed individually or in combination wherever possible.

1. A degradation diagnosis apparatus configured to diagnose progress of degradation of equipment in which a motor is installed, the degradation diagnosis apparatus comprising:
a dynamic eccentricity estimating unit configured to estimate a degree of dynamic eccentricity of a rotation shaft constituting the equipment based on a current flowing through the motor;
a static eccentricity estimating unit configured to estimate a degree of static eccentricity of the rotation shaft, based on the current flowing through the motor; and
a degradation diagnosis unit configured to diagnose a degree of shaft degradation related to the rotation shaft, based on the result of estimation, wherein
the degradation diagnosis unit is configured to diagnose the degree of shaft degradation related to the rotation shaft based on either one or both the result of estimation of the degree of static eccentricity and the result of estimation of the degree of dynamic eccentricity.

2. (canceled)

3. The degradation diagnosis apparatus of claim 1, wherein the static eccentricity estimating unit is configured to estimate the degree of static eccentricity based on a static eccentric rate being a ratio between a positive phase current and a negative phase current.

4. The degradation diagnosis apparatus of claim 1, wherein the dynamic eccentricity estimating unit is configured to estimate the degree of dynamic eccentricity based on an envelope against the current calculated by performing envelope processing.

5. The degradation diagnosis apparatus of claim 1, wherein
the dynamic eccentricity estimating unit is configured to estimate the degree of dynamic eccentricity based on a mechanical angle frequency of the motor obtained by applying frequency conversion to the current.

6. The degradation diagnosis apparatus of claim 1, wherein
the degree of shaft degradation related to the rotation shaft is diagnosed based on the current flowing through the motor when the motor is driven at a constant speed.

7. The degradation diagnosis apparatus of claim 1, wherein the degradation diagnosis unit is configured to diagnose the degree of shaft degradation by comparing the result of estimation with a predetermined threshold.

8. A degradation diagnosis system comprising:
a storage device configured to store data related to equipment in which a motor is installed, the data related to equipment being included in a signal sent via an electric communication circuit; and
a degradation diagnosis apparatus of claim 1, configured to diagnose a degree of shaft degradation related to the rotation shaft constituting the equipment based on data related to a current flowing through the equipment, the data related to a current being stored in the storage device.

9. (canceled)

10. A degradation diagnosing method of diagnosing progress of degradation in equipment in which a motor is installed, the method comprising:
estimating a degree of dynamic eccentricity of a rotation shaft included in the equipment, based on a current flowing through the motor;
estimating a degree of static eccentricity of the rotation shaft, based on the current flowing through the motor; and
diagnosing a degree of shaft degradation related to the rotation shaft, based on either one or both of a result of estimation of the degree of static eccentricity and the result of estimation of the degree of dynamic eccentricity.
